(19) United States
(12) Patent Application Publication
(10) Pub. No.: US 2012/0013191 A1
(43) Pub. Date: Jan. 19, 2012

(54) PHOTOVOLTAIC UNIT WITH ENERGY RECOVERY AND PHOTOLTAIC ASSEMBLY COMPRISING SUCH A UNIT

(75) Inventor: Jean-Claude Jeandeaud, Saint Marcel Bel Accueil (FR)

(73) Assignee: APOLLON SOLAR, LYON (FR)

(21) Appl. No.: 13/146,172

(22) PCT Filed: Jan. 25, 2010
(86) PCT No.: PCT/FR2010/050108

§ 371 Date: Sep. 29, 2011

(30) Foreign Application Priority Data
Jan. 26, 2009 (FR) 09 50447

(51) Int. Cl. H01L 31/05; H02J 1/10; H01L 31/02

(52) U.S. Cl. 307/80; 136/252; 136/244

(57) ABSTRACT

The invention relates to a photovoltaic unit (1A, 1B) including a supporting plate and a photovoltaic component (4A, 4B) that is arranged on the supporting plate and comprises an input connection element (6A, 6B) and an output connection element (8A, 8B). The unit further includes at least one first auxiliary circuit (14A, 14B), which is arranged on the supporting plate and can conduct electric current, and a first and a second connection terminal board (10A, 12A, 10B, 12B).

The present invention relates to a photovoltaic unit for recovering energy from solar radiation, often called “photovoltaic module”, and a photovoltaic assembly for recovering energy comprising such a unit.

Within the meaning of the invention, a photovoltaic solar unit is intended to be arranged on a structure, such as a roof or a frontage of a building, exposed to solar radiation.

In the context of this application, it is known to make use of a photovoltaic unit comprising a support on which is arranged a so-called “active” photovoltaic component.

Within the meaning of the invention, such a photovoltaic component takes the form of a panel comprising a plurality of interlinked individual photovoltaic cells. These cells are generally interposed between a transparent front plate, for example consisting of glass or of plastic material and intended to be exposed to the solar radiation, and a transparent or opaque backplate, for example consisting of glass or of TEDLAR (registered trademark) and intended to be arranged facing a mounting structure for the unit.

Such a photovoltaic component also comprises an input connection element and an output connection element. Since the photovoltaic unit is conventionally manufactured individually, it can thus be connected to other units by means of these two connection elements. As an example, if one unit delivers 100 V, a user wanting to obtain a structure generating 300 V connects three of these units in series. It is known, notably from FR-A-2 915 230 and from DE-A-197 39 948, to form photovoltaic units by arranging or fixing photovoltaic components on supports comprising connection elements. However, such implementations require connections between the units, notably by means of cables, to create photovoltaic assemblies according to specific requirements.

Each of these connections consists of a cable which hangs on the back of the unit. A number of qualified people are thus needed to handle the mounting, in a supporting structure, of a number of units intended to be connected, for example, to a headend.

The aim of the present invention is to provide a photovoltaic unit for recovering solar energy that is capable of being connected to an assembly of photovoltaic units, simply and easily, and minimizing the need for external connection elements such as cables.

To this end, the subject of the invention is a photo-voltaic unit for recovering energy from solar radiation, comprising:
a support plate,
a photovoltaic component arranged on the support plate and comprising an input connection element and an output connection element,
   characterized in that it also comprises:
at least one first auxiliary circuit, arranged on the support plate and suitable for conducting the electrical current,
a first and a second connection terminal block each comprising at least one first and one second connection terminal, the first terminal of the first terminal block being linked to the input connection element, the first terminal of the second terminal block being linked to the output connection element, at least the second terminals of each of the terminal blocks being linked by the auxiliary circuit,
a transparent plate arranged over the support plate, over the photovoltaic component and over the auxiliary circuit.

With the photovoltaic unit for recovering solar energy according to the invention, the connection to an assembly of photovoltaic units can easily be adapted to the wishes of the user concerning the voltage he/she wants to generate, once the overall structure is mounted. Furthermore, the connection between two units is possible on the side of their faces intended to be exposed to the solar rays.

According to other advantageous characteristics of the photovoltaic unit according to the invention, taken in isolation or in all technically possible combinations:
the unit comprises at least one second auxiliary circuit and the terminal blocks each comprise at least one third connection terminal, the two third terminals of each of the terminal blocks being linked by the second auxiliary circuit;
the unit comprises a third auxiliary circuit and the terminal blocks each comprise a fourth connection terminal, the two fourth terminals of each of the terminal blocks being linked by the third auxiliary circuit;
the first and/or the second and/or the third auxiliary circuit is formed by a continuous track;
the photovoltaic component is connected in series respectively with the first terminal of the first terminal block and with the first terminal of the second terminal block;
each connection terminal of the first connection terminal block is borne by a connection pin of this terminal block, extending relative to the support;
the connection pins of the first terminal block are made of a flexible material;
the unit comprises two additional auxiliary circuits for circulating an electrical control current.

Another object of the present invention is to provide a photovoltaic assembly for recovering energy from solar radiation, comprising:
at least two units arranged adjacent to one another, each of the units being as described above, and
at least one terminal borne by one of the connection pins of a first unit linked to a terminal of the terminal block of a second unit.

According to other advantageous characteristics of the photovoltaic assembly according to the invention, taken in isolation or in all technically possible combinations:
the photovoltaic assembly comprises at least two units arranged adjacent to one another, each of the units being as described above, and at least one connector, linking at least one terminal of a connection terminal block of a first unit to at least one terminal of a connection terminal block of a second unit;
at least two of the units are connected in series, a first terminal of the second terminal block linked to the output connection element of a first unit being connected to a first terminal of the first terminal block linked to the input connection element of the second unit;
at least two of the units are connected in parallel, a first terminal of the first terminal block linked to the output connection element of a first unit being connected to a first terminal of the first terminal block linked to the output connection element of the second unit;
at least two units are linked to a headend comprising two connection cables, suitable for circulating the current from the units;
at least two of the units are linked to a central current recovery module;
at least one connector comprises a protection means, such as a diode;
at least one of the connectors comprises a connection telltale, such as a light-emitting diode, designed to be in a first state when the connector is powered with current, and to be in a second state when the connector is not powered with current;
the assembly comprises a control circuit and at least one means for switching the flow of current from at least one unit connected to the control circuit and going to a headend to which this unit is linked, on the basis of an electrical signal transmitted by the control circuit;
the current switching means is a remote control switch or an electronic switch connected to the control circuit;
the current switching means is included in at least one connector linking two units;
current switching means are controlled individually or as a group from the control circuit on the basis of different signals.

The invention will be better understood from reading the following description, given solely as a nonlimiting example, and with reference to the drawings in which:

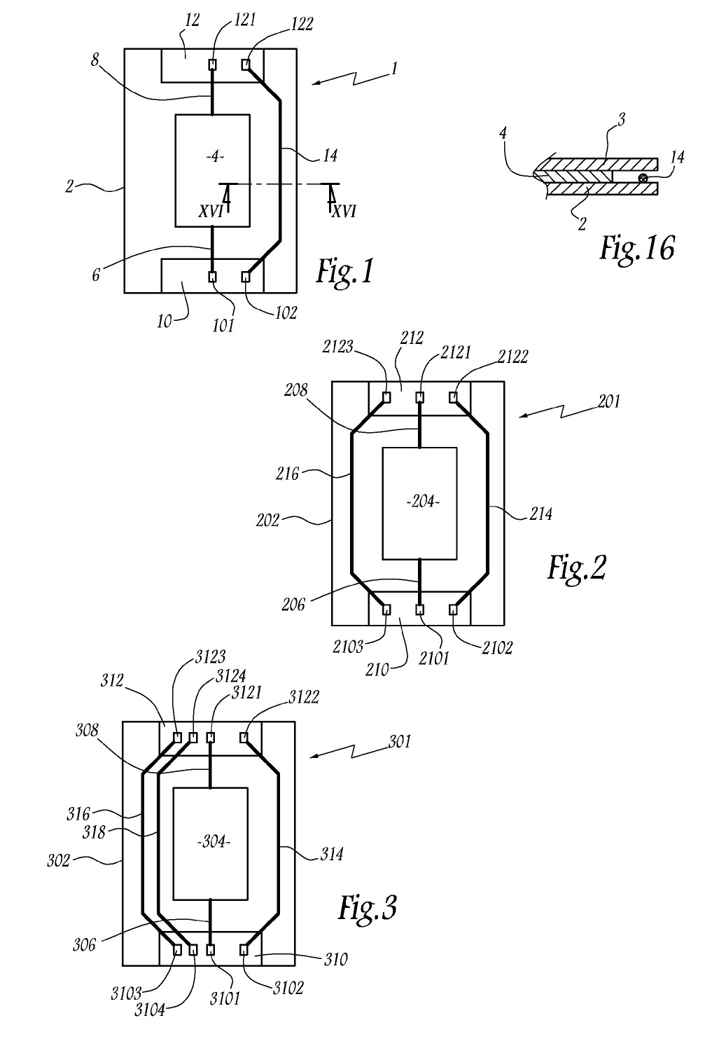

FIG. 1 is a schematic view of a photovoltaic unit according to a first embodiment of the invention;

FIG. 2 is a schematic view of a photovoltaic unit according to a second embodiment of the invention;

FIG. 3 is a schematic view of a photovoltaic unit according to a third embodiment of the invention;

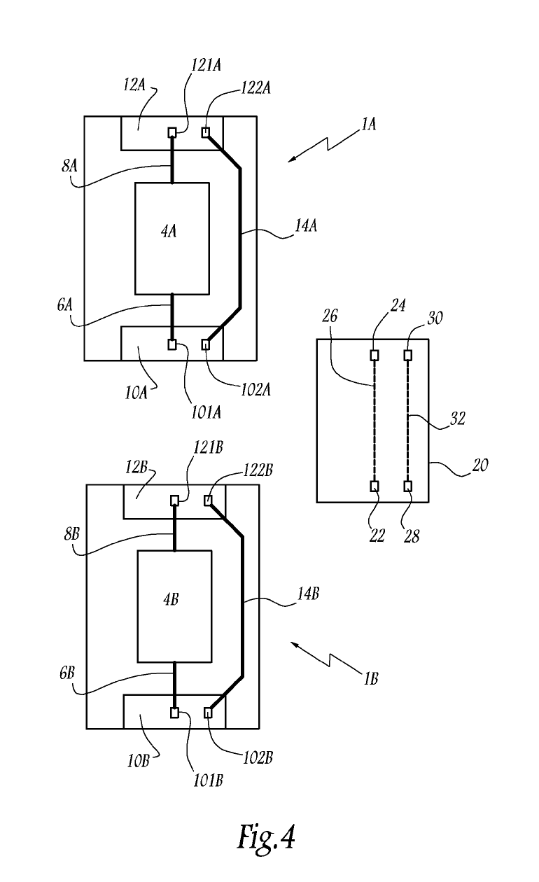

FIG. 4 is a schematic view of two units such as that represented in FIG. 1, before their connection;

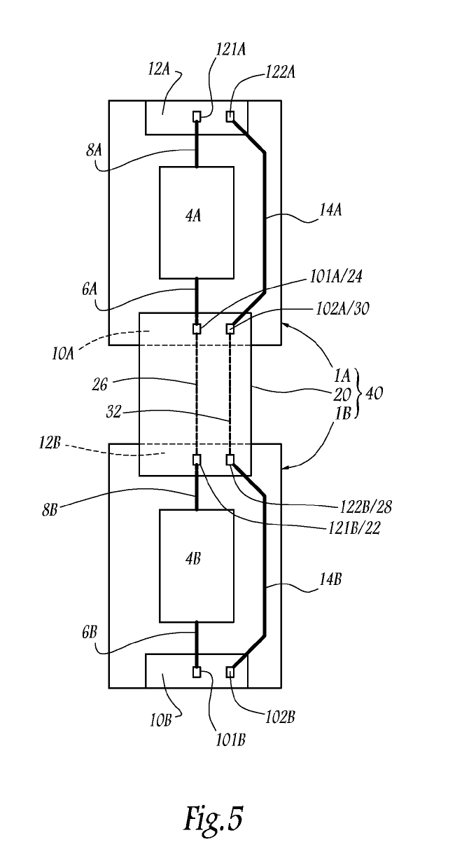

FIG. 5 is a schematic view of a photovoltaic assembly after the connection of the two units represented in FIG. 4;

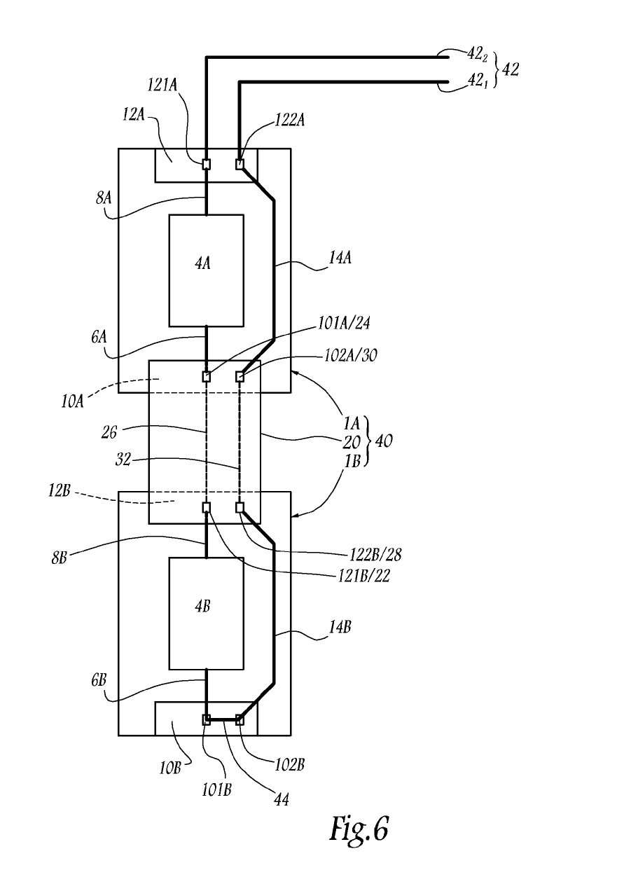

FIG. 6 is a schematic view of a photovoltaic assembly comprising two units connected in series;

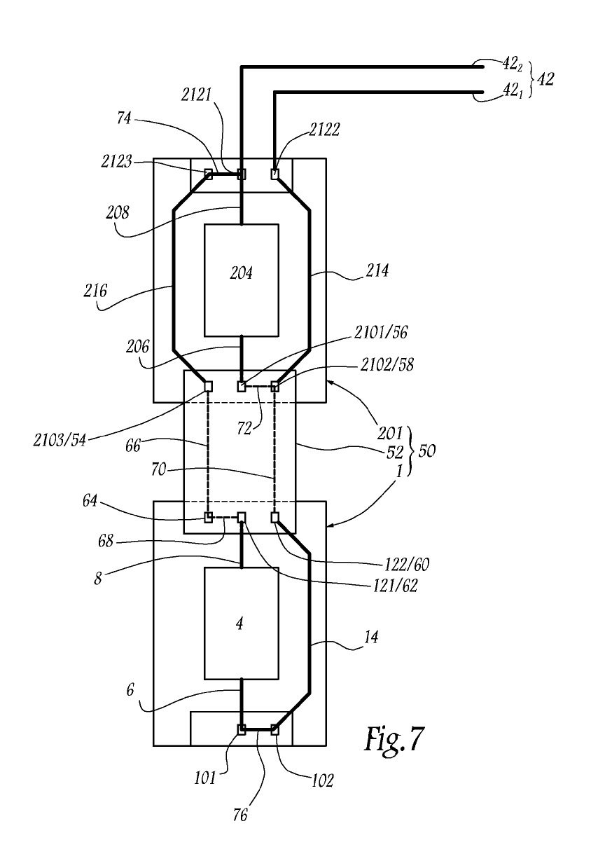

FIG. 7 is a schematic view of a photovoltaic assembly comprising two units connected in parallel;

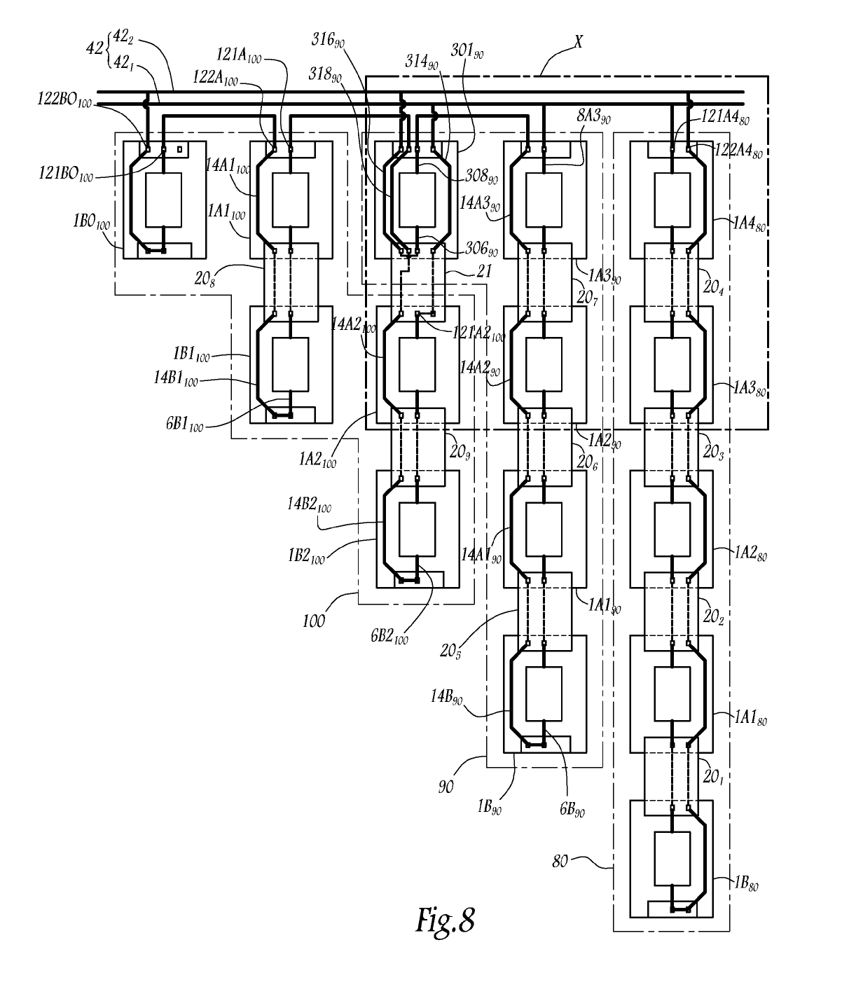

FIG. 8 is a schematic view of a mounting of three photovoltaic assemblies connected to a headend;

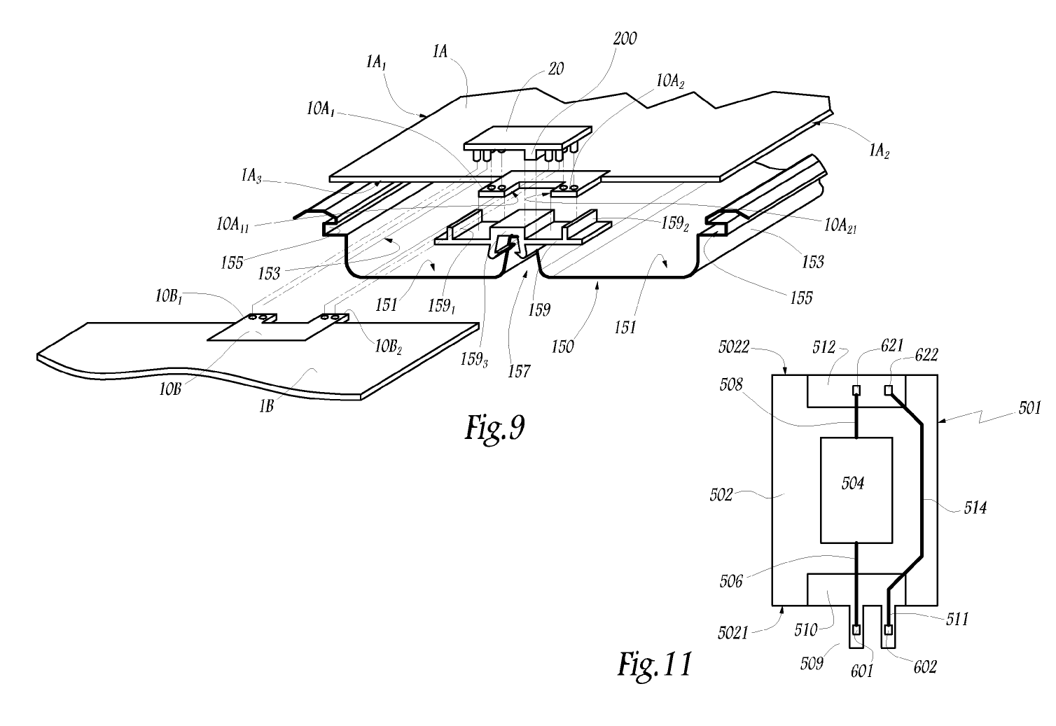

FIG. 9 is a partial view in perspective of two photovoltaic units before assembly;

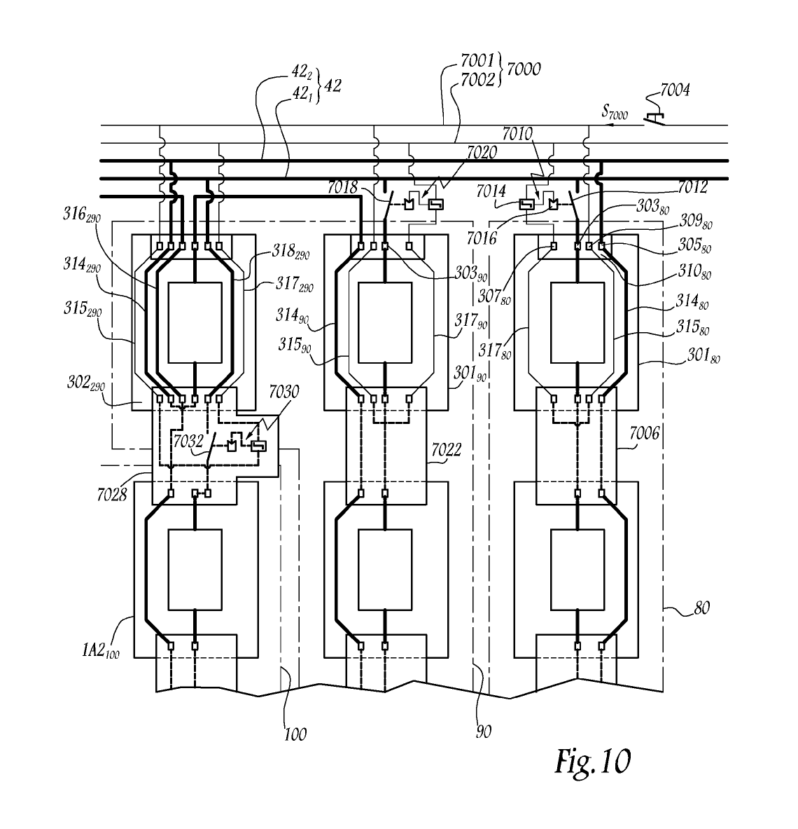

FIG. 10 is a schematic view of a portion, corresponding to the detail X in FIG. 8, of a mounting of three photovoltaic assemblies provided with electrical isolation means, connected to a headend and to a control circuit;

FIG. 11 is a schematic view of a photovoltaic unit according to a fourth embodiment of the invention;

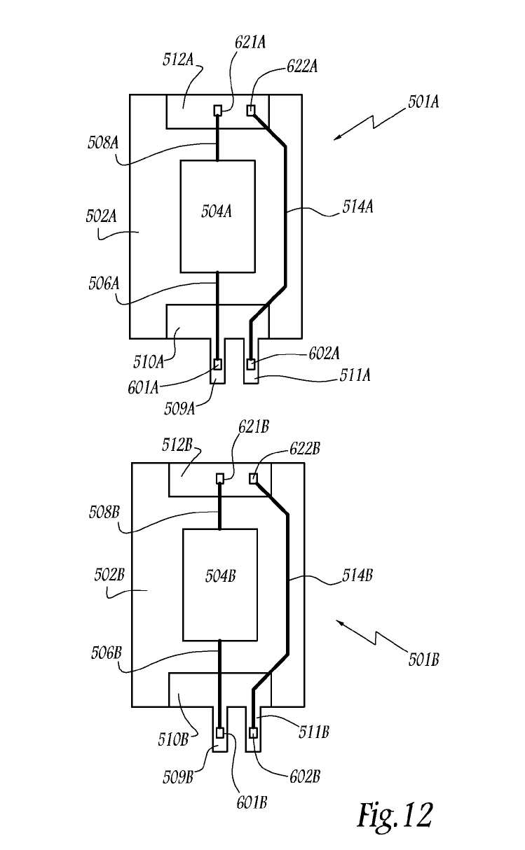

FIG. 12 is a schematic view of two units such as those represented in FIG. 11, before their connection;

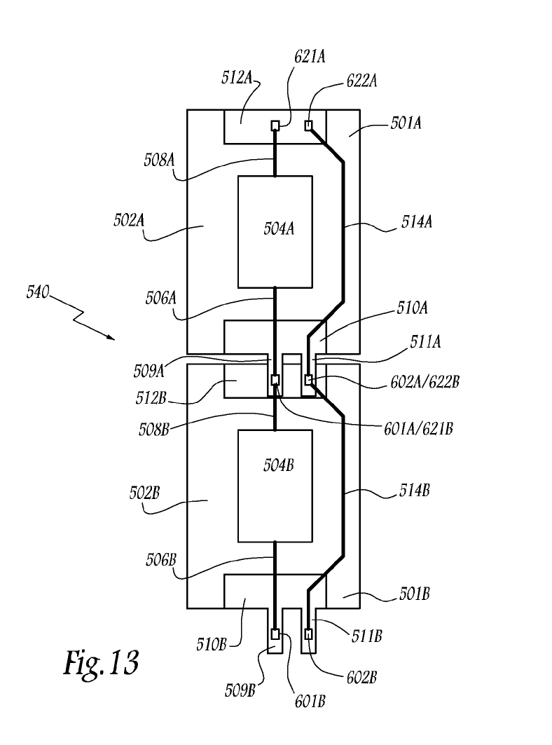

FIG. 13 is a schematic view of a photovoltaic assembly after the connection of two units represented in FIG. 12; and

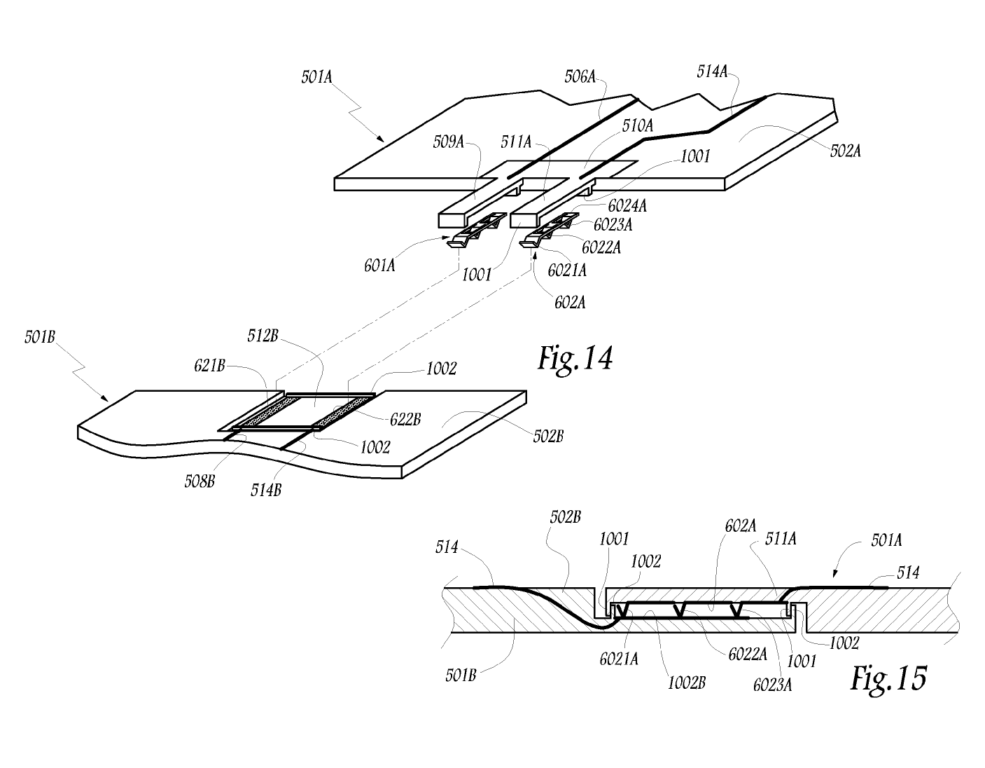

FIG. 14 is a partial exploded perspective view of two photovoltaic units such as those represented in FIG. 11, before assembly;

FIG. 15 is a theoretical cross section along the plane XV of FIG. 14, the units being connected together; and

FIG. 16 is a partial cross section of the unit of FIG. 1, along the plane XVI in FIG. 1.

FIG. 1 represents a photovoltaic unit 1 for recovering energy from solar radiation. Such a unit is sometimes called “photovoltaic module”. This unit 1 comprises a support 2 on which is arranged a photovoltaic component 4 forming the active part of the unit 1 and sometimes qualified as “active photovoltaic module”. The component 4 comprises an input connection element 6 and an output connection element 8, the connection elements being arranged opposite relative to the component 4. The component 4 comprises a plurality of individual photovoltaic cells that may be crystalline silicon wafers or thin films. The component 4 may also comprise a number of groups of such cells interconnected.

Furthermore, the unit 1 comprises, at two of its opposite ends, two connection terminal blocks 10 and 12. Each of the two terminal blocks 10 and 12 respectively comprises a first connection terminal 101, 121 and a second connection terminal 102, 122. The first terminal 101 of the terminal block 10 is connected in series to the component 4 by the input connection element 6, whereas the first terminal 121 of the second terminal block 12 is connected in series to the component 4 by the output connection element 8. The unit 1 also comprises an auxiliary circuit 14 attached to the support 2. This auxiliary circuit 14, which conducts electric current, provides the connection between the terminals 102 and 122.

FIG. 2 represents a photovoltaic unit 201 comprising a support 202 on which are arranged a photovoltaic component 204 and an auxiliary circuit 214. The component 204 is connected by its input 206 and output 208 connection elements, respectively in series to a first terminal 2101 of a terminal block 210 and to a first terminal 2121 of a terminal block 212. The auxiliary circuit 214 connects two respective second terminals 2102 and 2122 of the terminal blocks 210 and 212. The terminal blocks 210 and 212 also respectively each comprise a third terminal 2103 and 2123. These two terminals 2103 and 2123 are linked by a second auxiliary circuit 216 arranged on the support 202, facing the circuit 214 relative to the component 204.

The embodiment represented in FIG. 3 is a photo-voltaic unit 301 comprising a support 302 on which are arranged a photovoltaic component 304, a first auxiliary circuit 314, a second auxiliary circuit 316, and a third auxiliary circuit 318. The circuit 316 is adjacent to the circuit 318, which is in turn adjacent to the component 304. The circuit 314 is arranged substantially symmetrically to the circuit 316 relative to the component 304. The unit 301 also comprises two connection terminal blocks 310 and 312 each comprising four terminals respectively referenced 3101, 3102, 3103 and 3104 for the terminal block 310 and 3121, 3122, 3123 and 3124 for the terminal block 312. The component 304 is connected in series respectively to the terminals 3101 and 3121 by means of the input 306 and output 308 connection elements. The auxiliary circuit 314 connects the terminals 3102 and 3122, whereas the auxiliary circuit 316 connects the terminals 3103 and 3123 and the third auxiliary circuit 318 links the terminals 3104 and 3124.

The auxiliary circuits 14, 214, 216, 314, 316 and 318 may be cables or conductive electrical wires, attached to their respective support 2, 202 and 302 or even continuous tracks that may be printed like the support, for example copper tracks. The use of such tracks makes it possible to dispense with long cables arranged in insulated sheaths on the rear face of the photovoltaic units.

In order to add auxiliary circuits and multiply the connection possibilities, the auxiliary circuits of one and the same photovoltaic unit can be superposed and separated by layers of insulating material. This arrangement makes it possible to avoid overdimensioning the support plates 2 when adding additional auxiliary circuits. In order to insert circuit tracks, the support plates 2 may comprise several layers of materials.

As represented in FIG. 16 only for the unit 1, each of the units 1, 201 and 301 comprises a transparent plate 3 or equivalent arranged facing the support plates 2, 202 or 302, so that the tracks 14, 214, 216, 314, 316 and 318 and components 4, 204 and 304 are insulated and protected from bad weather. This transparent plate 3 or equivalent is sometimes qualified as “encapsulation plate”. Whereas the support plates 2, 202 and 302, which form the rear faces of the units 1, 201 and 301, may be of a transparent or opaque material, the transparent plates are made of a material that allows optimal passage of the solar radiation. A transparent plate forms the so-called exposed front face of a photovoltaic unit 1, 201 or 301. The thickness of a photovoltaic unit 1, 201, 301 therefore has, at the level of the photovoltaic component, a multilayer structure comprising, in succession, the support plate, the photovoltaic component and the transparent plate. FIG. 4 represents two units 1A and 1B identical to the unit 1 represented in FIG. 1. The two units are about to be connected by means of a connector 20. In the interests of clarity, the references indicated in FIG. 1 are complemented with an A when they relate to the unit 1A, and with a B when they relate to the unit 1B. The units 1A and 1B are arranged so that the terminal block 10A is facing the terminal block 12B.

The connector 20 comprises a bonding pad 22 linked to a bonding pad 24 by a connection element 26. The connector 20 also comprises a bonding pad 28 connected to a bonding pad 30 by a connection element 32. The connection elements 26 and 32 may be conductive wires or continuous tracks allowing for the conduction of the electrical current.

The units 1A and 1B are arranged so that the distance separating the terminal 101A from the terminal 121B is substantially identical to the distance separating the two pads 22 and 24. Similarly, the distance separating the terminal 102A and 122B is substantially identical to the distance separating the bonding pads 28 and 30.

Thus, the connector 20 can be mounted perpendicularly to the units 1A and 1B, so that the pads 22, 28, 24 and respectively cooperate with the terminals 121B, 122B, 101A and 102A.

Once the connection is made, the result is a photo-voltaic assembly 40 as represented in FIG. 5. In this assembly 40, it can be seen that the input connection element 6A of the unit 1A is connected to the output connection element 8B of the unit 1B by means of the element 26. Thus, the photovoltaic components 4A and 4B are connected in series. Similarly, the auxiliary circuit 14A is connected to the auxiliary circuit 14B by the connection element 32. It can be seen that the presence of the connector 20 implies an absence of cables in the connection area between the units 1A and 1B. The pre-mounting of such an assembly 40 is thus simplified. Furthermore, this pre-mounting is made all the easier since the connection can be made on the front face of the photovoltaic assembly, namely on the face arranged to be exposed to the solar rays.

FIG. 6 represents an assembly 40 connected to a headend 42 comprising two connection cables 42₁ and 42₂. The connection cable 42₁ is connected to the terminal 122A of the terminal block 12A of the unit 1A. The connection cable 42₂ is connected to the terminal 121A. Furthermore, a connection element 44 is arranged between the terminals 101B and 102B of the terminal block 10B of the unit 1B.

Thus, the units 1A and 1B are connected in series between the cables 42₂ and 42₂. In fact, the output connection element 8B of the component 4B of the unit 1B is linked to the input connection element 6A of the component 4A of the unit 1A. Furthermore, since the input connection element 6B of the component 4B is connected to the cable 42₂ and the output connection element 8A is connected to the cable 42₂, an electrical current can flow between the two components 4A and 4B.

If each of the units 1A and 1B delivers, between its terminals 101A and 121A, 101B and 121B, a voltage of 100 V, the assembly 40 delivers a voltage of 200 V between its terminals 121A and 122A. The user can produce a photovoltaic assembly comprising more than two units connected in series, two adjacent units being connected by a connector of the type of the connector 20. He/she can thus pre-mount a suitable number of units depending on the voltage that he/she wants to generate.

FIG. 7 represents an assembly 50 connected to a headend 42. The assembly 50 comprises a unit 201 connected to a unit 1 by means of a connector 52. The connector 52 comprises six bonding pads 54, 56, 58, 60, 62 and 64. The pad 54 is connected to the pad 64 via a connection element 66. The bonding pads 62 and 64 are linked by a connection element 68. The bonding pad 60 is connected to the bonding pad 58 by a connection element 70, the pad 58 being connected to the pad 56 by a connection element 72. The connection elements 66, 68, 70 and 72 may be conductive wires or continuous tracks incorporated in the connector 52 and allowing for the conduction of the electrical current.

Once the connector 52 is mounted perpendicularly between the units 1 and 201, the terminal 2123 is connected to the connection element 8 of the unit 1. The terminal 2123 is also connected to the terminal 2121 by means of a connection element 74. The connection element 6, just like the connection element 206, are connected to the pad 58 because of the connection between the terminals 101 and 102 by a connection element 76.

Thus, the units or modules 1 and 201 are connected in parallel. In fact, the connection elements 8 and 208 of the components 4 and 204 are linked to the cable 42₂ whereas the connection elements 6 and 206 are linked to the cable 42₁. If each of the units 1 and 201 delivers a voltage of 100 V, the assembly 50 delivers a voltage of 100V. The user can produce, as required, a photo-voltaic assembly comprising more than two units connected in parallel.

Moreover, the unit 1 or 201 can be replaced by an assembly of two units connected in series, as illustrated in FIG. 6, bearing in mind that provision may be made to link more than two units in series.

Similarly, each of the units 1A and 1B of the photo-voltaic assembly 40 represented in FIG. 6 can be replaced by an assembly of units connected in parallel, as represented in FIG. 7.

In other words, each of the units 1, 1A, 1B and 201, represented in FIGS. 6 and 7, can be replaced by one of the assemblies of units comprising at least two units represented in FIGS. 1 to 3, connected in parallel or in series by means of a connector, designed to provide the desired connection.

It is thus possible to note the advantage of modularity offered by the invention. The installer can connect a number of photovoltaic units in a matrix form, depending on the voltage that he/she wants to obtain. He/she can connect the units qualified as individual units 1, 201 and 301 using the appropriate connector, namely a connector having between two and four bonding pads at each of its two ends. Implementing such a matrix mounting is made simpler for specialist operatives, because of the absence of wiring. This type of implementation can thus be pre-mounted in the workshop before installation on a roof or a frontage.

In an example of matrix implementation of a photo-voltaic assembly, each of the columns can be connected to the headend 42. It is also possible to provide for each of the columns to be able to be directly connected to a central electric current recovery module.

FIG. 8 represents three examples of photovoltaic assemblies 80, 90 and 100, each of the assemblies being connected to a headend 42. In the interests of clarity, each of the references concerning the photovoltaic units is complemented in index form with the reference of the assembly and the reference letter A or B is incremented by one unit relative to the references used in FIGS. 1 to 7.

The assembly 80 comprises five photovoltaic units 1B₈₀, 1A1₈₀, 1A2₈₀, 1A3₈₀ and 1A4₈₀ connected in series, in a manner similar to the assembly 40 represented in FIG. 6 and comprising two units.

The unit 1B₈₀ is connected in series to the unit 1A1₈₀ by means of a connector 20₁, this unit 1A1₈₀ being in turn linked to the unit 1A2₈₀ by a connector 20₂. Furthermore, the unit 1A2₈₀ is connected in series to the unit 1A3₈₀ by a connector 20₃. The unit 1A4₈₀ is linked both to the unit 1A3₈₀ by a connector 20₄ and to the two connection cables 42₁ and 42₂ respectively via its terminals 121A4₈₀ and 122A4₈₀. The four connectors 20₁ to 20₄ are identical to the connector 20 represented in FIG. 6.

The assembly 90 comprises five units 301₉₀, 1B₉₀, 1A1₉₀, 1A2₉₀ and 1A3₉₀ connected in series and connected to the headend 42, these five units being distributed over two columns. The connection element 306₉₀ of the unit 301₉₀ is connected to the connection cable 42₂ via the track 316₉₀. The connection element 308₉₀ is linked to the connection element 6B₉₀ of the unit 1B₉₀ via, in succession, the auxiliary circuits 14A3₉₀, 14A2₉₀, 14A1₉₀ and 14B₉₀ respectively belonging to the units 1A3₉₀, 1A2₉₀, 1A1₉₀ and 1B₉₀. The connection element 8A3₉₀ of the unit 1A3₉₀ is connected to the connection cable 42₁. The units 1B₉₀, 1A1₉₀, 1A2₉₀ and 1A3₉₀ are respectively linked by connectors 20₅, 20₆ and 20₇, similar to the connector 20. By virtue of the auxiliary circuits 14A3₉₀, 14A2₉₀, 14A1₉₀ and 14B₉₀, a series connection of photovoltaic units arranged in two distinct columns is possible.

The assembly 100 comprises five units 1B0₁₀₀, 1B1₁₀₀, 1A1₁₀₀, 1B2₁₀₀ and 1A2₁₀₀ connected in series and arranged over three columns. The first column comprises the unit 1B0₁₀₀, whereas the second column comprises the two photovoltaic units 1B1₁₀₀, 1A1₁₀₀ connected in series by a connector 20₈. The terminal 122B0₁₀₀ of the unit 1B0₁₀₀ is connected to the connection cable 42₂, whereas its terminal 121B0₁₀₀ is connected to the connection element 6B1₁₀₀ of the last unit 1B1₁₀₀ of the second column by means of the tracks 14A1₁₀₀ and 14B1₁₀₀ respectively belonging to the units 1A1₁₀₀ and 1B1₁₀₀. The terminal 121A1₁₀₀ is connected to the connection element 6B2₁₀₀ of the last unit 1B2₁₀₀ of the third column via, in succession, the tracks 318₉₀, 14A2₁₀₀ and 14B2₁₀₀. The unit 1B2₁₀₀ is connected to the unit 1A2₁₀₀ by a connector 20₉, whereas the unit 1A2₁₀₀ is connected to the unit 301₉₀ by a connector 21. The terminal 121A2₁₀₀ is connected to the connection cable 42₁, notably by means of the track 314₉₀. It can therefore be seen that the assembly 100 uses only the auxiliary circuits 318₉₀ and 314₉₀ of the unit 301₉₀.

Thus, the invention enables the installer to adapt the number of photovoltaic units to be connected according to the surface area that he/she has available to obtain the desired voltage. The advantage of modularity offered by the present invention enables this installer to perform a pre-mounting of the photovoltaic assemblies. In the example represented, the truncated form of the mounting of FIG. 8 is adapted to its installation at the edge of a roof, at the join between two buildings whose ridge lines are not parallel, the roof edge then being inclined relative to its ridge.

Obviously, other mounting structures can be envisaged with the invention, for example with columns of the same lengths in which all the units are in series, each column being connected in parallel to the headend.

It can be seen that each of the units of the assembly 80 and of the assembly 100, and the units 1B₉₀, 1A1₉₀, 1A2₉₀ and 1A3₉₀ of the assembly 90 correspond to a unit such as the one defined in FIG. 1, namely a unit comprising a single auxiliary circuit. It is understood that each of these units can be replaced by a unit represented in FIG. 2 or by a unit represented in FIG. 3. In other words, units comprising two or three auxiliary circuits can be used in the assemblies 80, 90 and 100, except for the unit 301₉₀ which must necessarily have three auxiliary tracks.

Moreover, it should be noted that the units 1A1₈₀, 1A2₈₀, 1A3₈₀ and 1A4₈₀ on the one hand, and the units 1A1₉₀, 1A2₉₀, 1A3₉₀ and 1A1₁₀₀ on the other hand, are indeed identical, although their respective auxiliary track is arranged to the right of the active photovoltaic component for the units 1A1₈₀, 1A2₈₀, 1A3₈₀ and 1A4₈₀ and to the left for the units 1A1₉₀, 1A2₉₀, 1A3₉₀ and 1A1₁₀₀. Provision can also be made for the units 1A1₈₀ to 1A4₈₀ to be rotated by a half-turn. Similarly, the connectors 20₂ to 20₄ can make this half-revolution and continue to provide the connection between these units. The connector 20₁ is then suitable to provide for connection between the unit 1A1₈₀ and 1B₈₀. Thus, this flexibility of installation makes the mounting of such units easier.

FIG. 9 represents a preferential method of installing two photovoltaic units 1A and 1B on a support device 150. The device 150 has a profiled structure comprising a bottom 151 and two lateral wings 153. Each of the lateral wings forms a groove 155 arranged each to receive a longitudinal edge 1A₁ or 1A₂ of the unit 1A. The bottom 151 comprises a central reinforcing rib 157 extending longitudinally along the support 150.

At the end of the rib 157 there is a securing device 159. The device 159 is attached to the rib 157 and comprises, on either side of the rib 157, two guiding elements 159₁ and 159₂ designed to be in contact with a longitudinal outer edge of each of the two portions 10A₁ and 10A₂ of the terminal block 10A which extend beyond the main part of the unit 1A from its end edge 1A₃ perpendicular to its longitudinal edges. These two guiding elements 159₁ and 159₂ are arranged to facilitate the placement of the unit 1A in the support device 150. The securing device 159 also comprises a central guiding element 159₃ designed to be in contact with a longitudinal inner edge 10A₁₁ of the protruding portion 10A₁ of the terminal block 10A. It can be seen that the longitudinal inner edge 10A₂₁ of the second protruding portion 10A₂ of the terminal block 10A is not in contact with the central element 159₃ once the unit 1A is mounted in the support device 150. In other words, the lateral distance separating the two protruding portions of the terminal block 10A is greater than the width of the body 159₃.

Similarly, the photovoltaic unit 1B comprises a terminal block 10B provided with protruding portions 10B₁ and 10B₂, each of the portions having two connection terminals.

In this embodiment, the connector 20 has four bonding pads on each of its sides. It also has a centering element 200 arranged to be inserted in the space left vacant between the guiding element 159₃ and the protruding portion 10A₂ and 10B₂ of each of the terminal blocks 10A and 10B. This centering element 200 facilitates the placement of the connector 20 and also makes it possible to immobilize the units 1A and 1B relative to the support device 150.

Firstly, the unit 1A is placed in the support device 150 so that each of its longitudinal edges 1A₁ and 1A₂ cooperate with each of the grooves 155. At the same time, the protruding portions 10A₁ and 10A₂ bear on the device 159.

Secondly, the unit 1B is placed in a support device not represented and adjacent to the device 150. The protruding portions 10B₁ and 10B₂ are arranged bearing on the device 159, so that the respective front edges of the portions 10A₁ and 10B₁ on the one hand, and the respective front edges of the portions 10A₂ and 10B₂ on the other hand are in contact.

Thirdly, the connector 20 is gripped in each of the terminal blocks 10A and 10B. More specifically, each of the four bonding pads of the connector 20 located at the level of the protruding portions 10A₂ and 10A₂ is inserted into each of the four terminals of the terminal block 10A, whereas each of the four bonding pads of the connector located at the level of protruding portions 10B₂ and 10B₂ is inserted into each of the four terminals of the terminal block 10B. The four bonding pads that can be seen on the left in FIG. 9 are inserted into the two terminals of each of the protruding portions 10A₂ and 10B₂. Similarly, the four bonding pads that can be seen on the right in FIG. 9 are inserted into the two terminals of each of the protruding portions 10A₂ and 10B₂. Thus, the electrical connection of the units 1A and 1B is provided by the connector 20, without the use of dangling cables.

The different types of connectors used to connect two units 1, 201 or 301 may comprise protection means for protecting the photovoltaic components 4, 204 and 304 in the case where lightning might strike the photo-voltaic assembly. As a nonlimiting example, this protection means may be a diode. The connectors may also comprise a means for isolating the photovoltaic assemblies from the electricity network, such as a remotely-controllable switch, used in the case where intervention is necessary in a building provided with photovoltaic assemblies. Such devices are necessary in the case where emergency or service teams have to intervene in the building. Making the building electrically safe is a precondition to the entry and intervention, among others, of firefighters.

FIG. 10 partially represents photovoltaic assemblies 80, 90 and 100, each being connected to a control circuit 7000 having two cables 7001 and 7002. The cable 7001 is connected to a switch 7004, enabling a person to send an electrical signal S₇₀₀₀.

The photovoltaic assembly 80 is connected to the headend 42 via a photovoltaic unit 301₈₀, comprising three auxiliary circuits 314₈₀, 315₈₀ and 317₈₀. The auxiliary circuit 314₈₀ allows the current produced in the assembly 80 to flow, whereas the auxiliary circuits 315₈₀ and 317₈₀ allow a control current to flow. In practice, the unit 301₈₀ may be identical to the unit 301, while being used differently since only one of its auxiliary circuits conveys the current produced.

The unit 301₈₀ is connected to the headend 42 via two terminals 303₈₀ and 305₈₀. The unit 301₈₀ is also connected to the control circuit 7000 via two terminals 307₈₀ and 309₈₀. The terminals 303₈₀, 305₈₀, 307₈₀ and 309₈₀ form parts of the first terminal block 310₈₀ of the unit 301₈₀. The terminal 309₈₀ is directly connected to the cable 7001 of the control circuit 7000, downstream of the switch 7004. The terminal 309₈₀ is linked to the terminal 307₈₀ via the two auxiliary circuits 315₈₀ and 317₈₀ of the unit 301₈₀, and by a circuit linking two terminals of a connector 7006 connecting the units 301₈₀ and 1A3₈₀. The terminal 307₈₀ is connected to the cable 7002 of the control circuit 7000. Between the cable 7002 and the terminal 307₈₀ is connected a remote control switch 7010 designed to selectively open and close the circuit linking the terminal 303₈₀ and the cable 42₁ of the headend 42 at the level of a switch 7012. This remote control switch 7010 consists of a coil 7014, electrically connected to a trip 7016 designed to open the switch 7012.

The way it works is as follows. If needed, the switch 7004 is activated manually or remotely, sending, via the cable 7001, a control signal S₇₀₀₀ in the form of an electrical pulse. This electrical pulse S₇₀₀₀ passes through two auxiliary circuits 315₈₀ and 317₈₀ of the unit 301₈₀ to the coil 7014. This activates the trip 7016 which opens or closes the switch 7012, depending on its position before the activation of the switch 7004. If the switch 7012 was in the closed position, with the assembly 80 then outputting electrical current into the headend 42, the pulse given by actuating the switch 7004 then opens the circuit, preventing the photovoltaic assembly 80 from outputting current into the headend 42. In this case, this portion of the installation is then secured. To reclose the circuit and reactivate the production of electrical current from the assembly 80, a new activation of the switch 7004 is necessary in order to reclose the switch 7012.

The photovoltaic assembly 90 can be isolated from the headend 42 according to the same principle. The unit 1A3₉₀ represented in FIG. 8 is replaced by a unit 301₉₀, comprising three auxiliary circuits 314₉₀, 315₉₀ and 317₉₀. In practice, the units 301₈₀ and 301₉₀ are identical. A terminal 303₉₀ of this unit 301₉₀ is linked to the cable 42₁ from the headend 42. The unit 301₉₀ is also linked to the control circuit 7000. As described previously for the photovoltaic assembly 80, the photo-voltaic assembly 90 can be isolated from the headend by opening a switch 7018, inserted between the terminal 303₉₀ and the cable 42₁, by means of a remote control switch 7020. This remote control switch 7020 operates in the same way as the switch 7010, in that it is operated by the pulse S₇₀₀₀ given by the switch 7004 from the control circuit 7000. Pulse S₇₀₀₀ is transmitted to the remote control switch 7020 via the auxiliary circuits 315₉₀ and 317₉₀ of the unit 301₉₀ and via two interconnected terminals of a connector 7022 identical to the connector 7006 linking the unit 301₉₀ and the unit 1A2₉₀.

To isolate the photovoltaic assembly 100 from the headend 42, a remote control switch 7030 similar to the remote control switches 7010 and 7020 is used. Since the photovoltaic assembly 100 is linked to the headend 42 via the auxiliary circuits of a photovoltaic unit 302₉₀ belonging to the photovoltaic assembly 90, the remote control switch 7030 must be placed at the level of the connection between the unit 302₉₀ belonging to the assembly 90 and a photovoltaic unit 1A2₁₀₀ belonging to the assembly 100.

A connector 7028 is used to connect the units 7050 and 1A2₁₀₀. This connector 7028 comprises, on one side, six terminals and on the other side, three terminals.

Between two opposite terminals of the connector 7028, a switch 7032 is inserted which can be actuated by the remote control switch 7030. Opening this switch 7032 breaks the connection between the unit 1A2₁₀₀ and the headend 42, so isolating the photovoltaic assembly 100. The remote control switch 7030 for which the connector 7028 is provided, is connected to two terminals of the connector 7028.

To enable the remote control switch 7030 to be connected with the control circuit 7000, the unit 302₉₀ has two additional auxiliary circuits 315₂₉₀ and 317₂₉₀f bringing the number of auxiliary circuits of the unit 302₉₀ to five. These auxiliary circuits are represented in FIG. 10 as being arranged side by side. In practice, they may be superposed and inserted between insulating layers of the support plate of the unit 302₉₀.

Since the auxiliary circuits 315₈₀, 317₈₀, 315₉₀, etc., are dedicated to the flow of low-intensity control signals, they may be of small section compared to the auxiliary circuits 314₈₀ and equivalent.

FIG. 10 represents three portions of photovoltaic assemblies that can be isolated from the headend 42 by means of a pulse S₇₀₀₀ generated by a single switch and sent to three remote control switches 7010, 7020 and 7030 each controlling the isolation of one of the photovoltaic assemblies 80, 90 and 100. As a variant, each photovoltaic unit may be connected with an adjacent unit or with a headend by means of a connector provided with a remote control switch. It is also possible to envisage having the isolation of various photovoltaic assemblies or units controlled by various switches making it possible to selectively isolate the photovoltaic installations, by means of different electrical signals for each assembly. For example, a number of switches similar to switch 7004, designed to send, in the control circuit 7000, pulses of different intensities, frequencies or voltages can be implemented.

Switch 7004 represented in FIG. 10 is one of the means for isolating the photovoltaic assemblies that can be used in the context of the present invention. Other means such as remote controls, fuses or similar can be implemented depending in particular on the criteria mentioned in the building safety standards.

As a variant which is not represented, the switching means controlling the flow of current from the photo-voltaic assemblies 80, 90 and 100 or equivalent to the headend 42 is an electronic switch connected to the control circuit 7000, which can be activated by the signal S₇₀₀₀ or an equivalent signal. Such an electronic switch can also be activated remotely by a remote control.

Moreover, the connectors may also comprise a connection telltale, designed to indicate the state of the connection to the user. The connection telltale is notably in a so-called “on” state when the connector is powered with current, and in a so-called “off” state when the connector is not powered with current. As an example, this telltale may be a light-emitting diode.

Advantageously, such a connection telltale is arranged in a connector placed at the end of a block of photovoltaic units connected in series. Thus, if the telltale is in the “on” state, this enables the operation of the block as a whole.

As a nonlimiting example, the supports 2, 202 and 302 may be plates made of glass, of TEDLAR or of steel.

Furthermore, the connection at the level of the terminal blocks between, on the one hand, the connection elements and the terminals and, on the other hand, the bonding pads and the terminals, may be provided by a spring blade. Provision may also be made to use screw terminal blocks.

Provision may also be made to use a flexible element at the level of the connector to allow for the differential expansions between the various bodies forming a photovoltaic assembly to be taken up. As an example, the connector may have a flexible support, and the contact between a bonding pad and a terminal may be provided with a relative slip capability.

In the fourth embodiment of the invention represented in FIG. 11, a photovoltaic unit 501 comprises a support 502 on which is arranged an active photovoltaic component 504. In the vicinity of a first edge 5021 of the support 502, the unit 501 comprises two connection pins 509 and 511 each respectively bearing a connection terminal 601 and 602. The pins 509 and 511 belong to a terminal block 510. Furthermore, the unit 501 comprises, in the vicinity of an edge 5022 of the support 502 which is opposite to the edge 5021, a connection terminal block 512. The terminal block 512 comprises a first connection terminal 621 and a second connection terminal 622.

The pins 509 and 511 extend in protrusion relative to the support 502, in that they protrude relative to the edge 5022, facing the support which extends between the edges 5021 and 5022.

The terminal 601 is electrically connected in series to the component 504 by the input connection element 506, whereas the terminal 621 of the terminal block 512 is electrically connected in series to the component 504 by the output connection element 508.

Each pin is made of a flexible plastic material, so that it can be deformed in a direction perpendicular to the plane of FIG. 1, which facilitates the connection of a terminal 601, 602, to a terminal of a second terminal block of another unit.

The unit 501 also comprises an auxiliary circuit 514 which provides the connection between the terminals 602 and 622. The connection pin 509 partly supports the input connection element 506, whereas the pin 511 partly supports the auxiliary circuit 514.

FIG. 12 represents two units 501A and 501B that are identical to the unit 501 represented in FIG. 11. The two units are about to be connected by means of the connection pins 509A and 511A of the unit 501A. In the interests of clarity, the references indicated in FIG. 11 are complemented with an A when they relate to the unit 501A, and with a B when they relate to the unit 501B. The units 501A and 501B are arranged so that the connection pins 509A and 511A, namely the terminal block 510A, are facing the terminal block 512B.

The units 501A and 501B are arranged so that the distance separating the terminal 601A from the terminal 602A is substantially identical to the distance separating the terminal 621B from the terminal 622B of the terminal block 512B of the unit 501B. Thus, the connection pins 509A and 511A can be mounted perpendicularly on the terminal block 512B, so that the terminals 601A and 602A respectively cooperate with the terminals 621B and 622B.

Once the connection is made, the result is a photo-voltaic assembly 540 as represented in FIG. 13. In this assembly 540, it can be seen that the input connection element 506A of the unit 501A is connected to the output connection element 508B of the unit 501B by means of the connection between the terminal 601A and the terminal 621B. Thus, the photovoltaic components 504A and 504B are connected in series. Similarly, the auxiliary circuit 514A is connected to the auxiliary circuit 514B by the connection pin 511A and more specifically by virtue of the connection between the terminals 602A and 622B.

The presence of the connection pins implies an absence of connection element external to the assembly 540 at the level of the connection area between the units 501A and 501B. Pre-mounting such an assembly 540 is thus made simpler. Furthermore, this pre-mounting is made all the simpler when the connection can be made on the front face of the photovoltaic assembly, namely on the face arranged to be exposed to the solar rays. The absence of a third-party connection element attenuates the current losses in the assembly 540 because fewer connection interfaces are used than if a connector were inserted between the units 501A and 501B. In fact, there is a direct electrical link between the unit 501A and 501B. There is not a first connection between the unit 501A and an external element, then a second connection between the external element and the unit 501B.

The photovoltaic units 501 of this embodiment are designed to create photovoltaic assembly mountings such as those represented in FIG. 8. In order to create parallel mountings of photovoltaic units 501 of this embodiment, it is necessary to use specific connectors making it possible to interlink the connection pins. However, the series mounting represents the most common use.

FIG. 14 represents a preferential method of connection of two photovoltaic units 501A and 501B, this connection method being able to be used with all the variants of the invention. The unit 501A comprises two flexible connection pins 509A and 511A each respectively provided with a terminal 601A and 602A. In FIG. 14, the terminals 601A and 602A are represented offset relative to the pins 509A and 511A, for the clarity of the drawing. The terminal 602A consists of a metal platelet which is perforated and locally bent so that it forms three elastically deformable tabs 6021A, 6022A and 6023A to bear on a terminal 622B which is formed by a planar metal platelet and belongs to a terminal block 512B of the unit 501B. The tabs 6021A to 6023A extend from a core 6024A of platelet 602A which is fixed to the pin 511A, for example by gluing. The terminal 601A is identical to the terminal 602A.

By way of a variant which is not represented, the platelets forming the terminals 601A and 602A may be produced of a single piece with the electrical tracks of the photovoltaic units, in order to eliminate the electrical losses at the interfaces. For example, the terminal 601A may be produced in a single piece with the input connection element 506A, and the terminal 602A may be produced in a single piece with the auxiliary circuit 514A.

The terminal block 512B comprises another terminal also formed by a planar metal platelet 621B and is formed set back relative to the top face of the unit 501B. As represented in FIG. 15, the tabs 6021A to 6023A provide a multipoint contact between the terminals 602A and 622B and thus link the circuits 514 of the units 501A and 501B. The elastic nature of these tabs makes it possible to compensate for any alignment defect that may exist between the bodies 502A and 502B of the units 501A and 501B.

As a nonlimiting example, the metal platelets may consist of copper or titanium.

In order to retain the elasticity of the platelets over time, and consequently a good electrical contact, a layer of elastic material may be added between each metal platelet and each connection pin. This makes it possible to avoid the relaxing of the electrical contact which is likely to occur in the case where the platelets are made of copper, because of the relative deterioration of the elastic qualities of the copper over time. To this end, additive materials such as foams or rubber may be used.

Moreover, a protection module is provided around the electrical connection area. This module provides protection for the contact area between the terminals 601A and 621B, on the one hand, and the terminals 602A and 622B on the other hand, in bad weather for example. This module consists of partitions 1001 and 1002 provided respectively on the pins 509A and 511A, on the one hand, and on the terminal block 512B, on the other hand. Seals may be fitted between the partitions 1001 and 1002 so as to insulate the connection area from rain.

According to a variant of the invention which is not represented, provision may be made, for each of the embodiments, for the two terminal blocks to be arranged on one and the same side of the support.

Each of the connection pins extends relative to the support. In other words, the pin of substantially longitudinal form protrudes from the support. Moreover, each of the connection pins may support a number of terminals.

The different connection pins used to connect two units 501 may comprise protection means providing protection for the photovoltaic components 504 in the case where lightning might strike the photovoltaic assembly. As a nonlimiting example, this protection means may be a diode.

Moreover, the connection pins may also comprise a connection telltale, designed to indicate the state of the connection to the user. The connection telltale is notably in an “on” state when the pin is powered with current, and in an “off” state when the pin is not powered with current. As an example, this telltale may be a light-emitting diode. Advantageously, such a connection telltale is arranged in a pin placed at the end of a block of photovoltaic units connected in series and linked to a connection cable. Thus, if the telltale is in the “on” state, this enables the operation of the block as a whole.

As a variant, the auxiliary circuits used in most of the embodiments described above may be implemented together with auxiliary cables. To this end, the addition of devices for adapting to a cable connection to the connectors and to the units may be envisaged, making it possible, if necessary, to add an auxiliary circuit in the form of a cable to a photovoltaic unit, in order to avoid using another type of photovoltaic unit which might not be available.

The characteristics of the various embodiments described above may be combined in the context of the present invention; in particular the connection pins made of flexible material of the embodiments of FIGS. 11 to 15 may notably be implemented together with the connectors described in the embodiments of FIGS. 4 to 10. The switching means for controlling the flow of current, and the additional auxiliary circuits used to implement them described in FIG. 10, are compatible with the connection pins made of flexible material described in FIGS. 11 to 15.

1-20. (canceled)

21. A photovoltaic unit for recovering energy from solar radiation, comprising:
a support plate,
a photovoltaic component arranged on the support plate and comprising an input connection element and an output connection element,
characterized in that it also comprises:
at least one first auxiliary circuit, arranged on the support plate and suitable for conducting the electrical current,
a first and a second connection terminal block each comprising at least one first and one second connection terminal, the first terminal of the first terminal block being linked to the input connection element, the first terminal of the second terminal block being linked to the output connection element,
at least the second terminals of each of the terminal blocks being linked by the auxiliary circuit,
a transparent plate arranged over the support plate, over the photovoltaic component and over the auxiliary circuit.

22. The unit as claimed in claim 21, characterized in that it comprises at least one second auxiliary circuit and in that the terminal blocks each comprise at least one third connection terminal, the two third terminals of each of the terminal blocks being linked by the second auxiliary circuit.

23. The unit as claimed in claim 22, characterized in that it comprises a third auxiliary circuit and in that the terminal blocks each comprise a fourth connection terminal, the two fourth terminals of each of the terminal blocks being linked by the third auxiliary circuit.

24. The unit as claimed in claim 21, characterized in that the first and/or the second and/or the third auxiliary circuit is formed by a continuous track.

25. The unit as claimed in claim 21, characterized in that the photovoltaic component is connected in series respectively with the first terminal of the first terminal block and with the first terminal of the second terminal block.

26. The unit as claimed in claim 21, characterized in that each connection terminal of the first connection terminal block is borne by a connection pin of this terminal block, extending relative to the support.

27. The unit as claimed in claim 26, characterized in that the connection pins of the first terminal block are made of a flexible material.

28. The unit as claimed in claim 21, characterized in that it comprises two additional auxiliary circuits for circulating an electrical control current.

29. A photovoltaic assembly for recovering energy from solar radiation, comprising:
at least two units arranged adjacent to one another, each of the units being as claimed in claim 26,
at least one terminal borne by one of the connection pins of a first unit linked to a terminal of the terminal block of a second unit.

30. A photovoltaic assembly for recovering energy from solar radiation, comprising:
at least two units arranged adjacent to one another, each of the units being as claimed in claim 1, and
at least one connector, linking at least one terminal of a connection terminal block of a first unit to at least one terminal of a connection terminal block of a second unit.

31. The assembly as claimed in claim 30, characterized in that at least two of the units are connected in series, a first terminal (121B) of the second terminal block linked to the output connection element of a first unit being connected to a first terminal of the first terminal block linked to the input connection element of the second unit.

32. The assembly as claimed in claim 30, characterized in that at least two of the units are connected in parallel, a first terminal of the first terminal block linked to the output connection element of a first unit (1) being connected to a first terminal of the first terminal block linked to the output connection element of the second unit.

33. The assembly as claimed in claims 30, characterized in that at least two units are linked to a head end comprising two connection cables, suitable for circulating the current from the units.

34. The assembly as claimed in claim 30, characterized in that at least two of the units are linked to a central current recovery module.

35. The assembly as claimed in claim 30, characterized in that at least one connector comprises a protection means, such as a diode.

36. The assembly as claimed in claim 30, characterized in that at least one of the connectors comprises a connection telltale, such as a light-emitting diode, designed to be in a first state when the connector is powered with current, and to be in a second state when the connector is not powered with current.

37. The assembly as claimed in claim 30, characterized in that it comprises a control circuit and at least one means for switching the flow of current from at least one unit connected to the control circuit and going to a headend to which this unit is linked, on the basis of an electrical signal transmitted by the control circuit.

38. The assembly as claimed in claim 37, characterized in that the current switching means is a remote control switch or an electronic switch connected to the control circuit.

39. The assembly as claimed in claim 37, characterized in that the current switching means is included in at least one connector linking two units.

40. The assembly as claimed in claim 37, characterized in that current switching means are controlled individually or as a group from the control circuit on the basis of different signals.
